(19) United States
(12) Patent Application Publication
(10) Pub. No.: US 2012/0053872 A1
(43) Pub. Date: Mar. 1, 2012

(54) SYSTEM AND METHOD FOR DETERMINING HUMIDITY BASED ON DETERMINATION OF AN OFFSET VOLTAGE SHIFT

(75) Inventors: Daniel Felnhofer, San Jose, CA (US); Wihelmus A. de Groot, Palo Alto, CA (US)

(73) Assignee: QUALCOMM MEMS TECHNOLOGIES, INC., San Diego, CA (US)

(21) Appl. No.: 12/869,045

(22) Filed: Aug. 26, 2010

(51) Int. Cl. G01R 19/155; G01N 27/12

(52) U.S. Cl. 702/64; 73/335.02

(57) ABSTRACT

A system and method for determining humidity based on determination of an offset voltage shift are disclosed. In one embodiment, a system for determining humidity comprises an electromechanical device comprising a first layer, a second layer, and a dielectric between the two layers, wherein the dielectric is spaced apart from at least one of the first and second layers in an unactuated state of the electromechanical device, and wherein the dielectric contacts both the first and second layers in an actuated state of the electromechanical device, a voltage source configured to apply, between the first and second layers, one or more voltages, and a processor configured to control the voltage source, to determine an offset voltage shift based on the applied voltages, and to determine information regarding humidity about the device based on the offset voltage shift.

### BACKGROUND

1. Field

The field of the invention relates to determining humidity information based on an offset voltage shift of a device.

2. Description of the Related Technology

Electromechanical systems (EMS) include devices having electrical and mechanical elements, actuators, transducers, sensors, optical components (e.g., mirrors), and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers or that add layers to form electrical and electromechanical devices. In the following description, the term MEMS device is used as a general term to refer to electromechanical devices, and is not intended to refer to any particular scale of electromechanical devices unless specifically noted otherwise.

One type of electromechanical systems device is called an interferometric modulator. As used herein, the term interferometric modulator or interferometric light modulator refers to a device that selectively absorbs and/or reflects light using the principles of optical interference. In certain embodiments, an interferometric modulator may comprise a pair of conductive plates, one or both of which may be transparent and/or reflective in whole or part and capable of relative motion upon application of an appropriate electrical signal. In a particular embodiment, one plate may comprise a stationary layer deposited on a substrate and the other plate may comprise a metallic membrane separated from the stationary layer by an air gap. As described herein in more detail, the position of one plate in relation to another can change the optical interference of light incident on the interferometric modulator. Such devices have a wide range of applications, and it would be beneficial in the art to utilize and/or modify the characteristics of these types of devices so that their features can be exploited in improving existing products and creating new products that have not yet been developed.

### SUMMARY

The system, method, and devices of the invention each have several aspects, no single one of which is solely responsible for its desirable attributes. Without limiting the scope of this invention, its more prominent features will now be discussed briefly. After considering this discussion, and particularly after reading the section entitled “Detailed Description” one will understand how the features of this invention provide advantages over other methods of determining information regarding humidity.

In one aspect, a method of determining information regarding humidity comprises determining an offset voltage shift of an electromechanical device and determining information regarding humidity about the device based on the offset voltage shift.

In another aspect, a system for determining humidity comprises an electromechanical device comprising a first layer, a second layer, and a dielectric between the two layers wherein the dielectric is spaced apart from at least one of the first and second layers in an unactuated state of the electromechanical device, and wherein the dielectric contacts both the first and second layers in an actuated state of the electromechanical device, a voltage source configured to apply, between the first and second layers, one or more voltages, and a processor configured to control the voltage source, to determine an offset voltage shift based on the applied voltages, and to determine information regarding humidity about the device based on the offset voltage shift.

In another aspect, a system for determining information regarding humidity comprises means for determining an offset voltage shift of an electromechanical device and means for determining information regarding humidity about the device based on the offset voltage shift.

In another aspect, a computer-readable storage medium has computer-executable instructions encoded thereon for performing a method of determining information regarding humidity, the method comprising determining an offset voltage shift of an electromechanical device and determining information regarding humidity about the device based on the offset voltage shift.

### BRIEF DESCRIPTION OF THE DRAWINGS

FIG. 1 is an isometric view depicting a portion of one embodiment of an interferometric modulator display in which a movable reflective layer of a first interferometric modulator is in a relaxed position and a movable reflective layer of a second interferometric modulator is in an actuated position.

FIG. 2 is a system block diagram illustrating one embodiment of an electronic device incorporating a 3×3 interferometric modulator display.

FIG. 3 is a diagram of movable mirror position versus applied voltage for one exemplary embodiment of an interferometric modulator of FIG. 1.

FIG. 4 is an illustration of a set of row and column voltages that may be used to drive an interferometric modulator display.

FIGS. 5A and 5B illustrate one exemplary timing diagram for row and column signals that may be used to write a frame of display data to the 3×3 interferometric modulator display of FIG. 2.

FIGS. 6A and 6B are system block diagrams illustrating an embodiment of a visual display device comprising a plurality of interferometric modulators.

FIG. 7A is a cross section of the device of FIG. 1.

FIG. 7B is a cross section of an alternative embodiment of an interferometric modulator.

FIG. 7C is a cross section of another alternative embodiment of an interferometric modulator.

FIG. 7D is a cross section of yet another alternative embodiment of an interferometric modulator.

FIG. 7E is a cross section of an additional alternative embodiment of an interferometric modulator.

FIG. 8A is a diagram of an embodiment of a capacitive EMS device.

FIG. 8B is a diagram of an embodiment of a capacitive EMS device in an actuated state.

FIG. 8C is a diagram of an embodiment of a capacitive EMS device in a released state.

FIG. 9A is a diagram of the gap distance between a first layer of a capacitive EMS device and a second layer of the capacitive EMS device versus voltage applied between the two layers.

FIG. 9B is a diagram of the gap distance versus voltage of FIG. 9A at a later time.

FIG. 10 is a plot of offset voltage shift versus applied voltage for different humidities.

FIG. 11 is a plot of offset voltage shift versus a stress time

FIG. 12 is a functional block diagram of a system for determining information regarding humidity.

FIG. 13 is a flowchart illustrating a method of determining information regarding humidity.

FIG. 14 is a flowchart illustrating a method of determining information regarding humidity over time.

FIG. 15 is a plot of offset voltage versus cumulative stress time.

FIG. 16 is a plot of adjusted offset voltage shift over time.

FIG. 17 is a plot of adjusted offset voltage shift versus humidity value for an exemplary embodiment.

FIG. 18 is a plot of humidity versus time for an exemplary embodiment.

### DETAILED DESCRIPTION

The following detailed description is directed to certain specific embodiments of the invention. However, the invention can be embodied in a multitude of different ways. In this description, reference is made to the drawings wherein like parts are designated with like numerals throughout. As will be apparent from the following description, the embodiments may be implemented in any device that is configured to display an image, whether in motion (e.g., video) or stationary (e.g., still image), and whether textual or pictorial. More particularly, it is contemplated that the embodiments may be implemented in or associated with a variety of electronic devices such as, but not limited to, mobile telephones, wireless devices, personal data assistants (PDAs), hand-held or portable computers, GPS receivers/navigators, cameras, MP3 players, camcorders, game consoles, wrist watches, clocks, calculators, television monitors, flat panel displays, computer monitors, auto displays (e.g., odometer display, etc.), cockpit controls and/or displays, display of camera views (e.g., display of a rear view camera in a vehicle), electronic photographs, electronic billboards or signs, projectors, architectural structures, packaging, and aesthetic structures (e.g., display of images on a piece of jewelry). MEMS devices of similar structure to those described herein can also be used in non-display applications such as in electronic switching devices.

Capacitive EMS devices, such as interferometric modulators, can be used to measure humidity by measuring the amount of surface charging of a dielectric between two layers of the device. This charging is sensitive to surface effects on either side of the air gap between the two layers, such as contamination and humidity. As the humidity about the device increases, the amount of surface charging in response to a particular stimulus increases. As the humidity decreases, the surface charging in response to the particular stimulus decreases. Aspects are described below which allow for determining, for example, in situ humidity of an EMS package which does not require additional testing structure within the package or additional fabrication steps.

One issue in the development of electrostatic EMS technology is that, as mentioned above, environmental parameters such as humidity can influence the performance and the reliable of EMS devices. Thus, in one embodiment, an EMS device operates within a sealed package such that the environmental parameters can be known, selected, or controlled. Packaging may be imperfect and the environmental parameters within the device may change. However, once a device is packaged, it can be difficult to determine the environmental parameters within the package without damaging the packaging.

In one embodiment, humidity within a package is controlled by depositing a desiccant within the package which absorbs moisture. Thus, the humidity in the package remains low. One method for determining the quality of a seal of a package with deposited desiccant is to weigh the package over time, as moisture is absorbed the desiccant increases in weight. These measurements can be time-consuming because weight gain may be small in comparison to the undesirable effects on performance. Another method for determining the quality of seal of a package is to fabricate or place a humidity sensor within the package. However, this may be disadvantageous as it requires fabrication processing or space within the package.

As mentioned above, aspects are described below which allow for determining humidity about an EMS device without an additional testing structure within the package or additional fabrication steps.

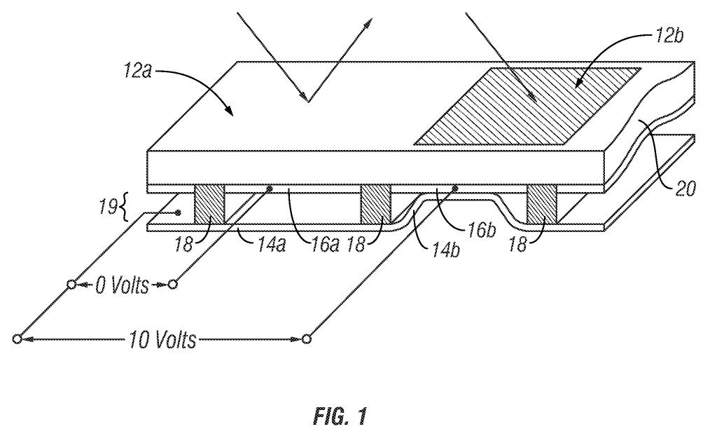

One interferometric modulator display embodiment comprising an EMS element, particularly an interferometric MEMS display element, is illustrated in FIG. 1. In these devices, the pixels are in either a bright or dark state. In the bright (“on” or “open”) state, the display element reflects (or transmit) a large portion of incident visible light to a user. When in the dark (“off” or “closed”) state, the display element reflects (or transmit) little incident visible light to the user. Depending on the embodiment, the light reflectance properties of the “on” and “off” states may be reversed. MEMS pixels can be configured to reflect predominantly at selected colors, allowing for a color display in addition to black and white.

FIG. 1 is an isometric view depicting two adjacent pixels in a series of pixels of a visual display, wherein each pixel comprises a MEMS interferometric modulator. In some embodiments, an interferometric modulator display comprises a row/column array of these interferometric modulators. Each interferometric modulator includes a pair of reflective layers positioned at a variable and controllable distance from each other to form a resonant optical cavity with at least one variable dimension. In one embodiment, one of the reflective layers may be moved between two positions. In the first position, referred to herein as the relaxed position, the movable reflective layer is positioned at a relatively large distance from a fixed partially reflective layer. In the second position, referred to herein as the actuated position, the movable reflective layer is positioned more closely adjacent to the partially reflective layer. Incident light that reflects from the two layers interferes constructively or destructively depending on the position of the movable reflective layer, producing either an overall reflective or non-reflective state for each pixel.

The depicted portion of the pixel array in FIG. 1 includes two adjacent interferometric modulators 12a and 12b. In the interferometric modulator 12a on the left, a movable reflective layer 14a is illustrated in a relaxed position at a predetermined distance from an optical stack 16a, which includes a partially reflective layer. In the interferometric modulator 12b on the right, the movable reflective layer 14b is illustrated in an actuated position adjacent to the optical stack 16b.

The optical stacks 16a and 16b (collectively referred to as optical stack 16), as referenced herein, typically comprise of several fused layers, which can include an electrode layer, such as indium tin oxide (ITO), a partially reflective layer, such as chromium, and a transparent dielectric. The optical stack 16 is thus electrically conductive, partially transparent and partially reflective, and may be fabricated, for example, by depositing one or more of the above layers onto a transparent substrate 20. In some embodiments, the layers are patterned into parallel strips, and may form row electrodes in a display device as described further below. The movable reflective layers 14a, 14b may be formed as a series of parallel strips of a deposited metal layer or layers (orthogonal to the row electrodes of 16a, 16b) deposited on top of posts 18 and an intervening sacrificial material deposited between the posts 18. When the sacrificial material is etched away, the movable reflective layers 14a, 14b are separated from the optical stacks 16a, 16b by a defined gap 19. A highly conductive and reflective material such as aluminum may be used for the reflective layers 14, and these strips may form column electrodes in a display device.

With no applied voltage, the cavity 19 remains between the movable reflective layer 14a and optical stack 16a, with the movable reflective layer 14a in a mechanically relaxed state, as illustrated by the pixel 12a in FIG. 1. However, when a potential difference is applied to a selected row and column, the capacitor formed at the intersection of the row and column electrodes at the corresponding pixel becomes charged, and electrostatic forces pull the electrodes together. If the voltage is high enough, the movable reflective layer 14 is deformed and is forced against the optical stack 16. A dielectric layer (not illustrated in this Figure) within the optical stack 16 may prevent shorting and control the separation distance between layers 14 and 16, as illustrated by pixel 12b on the right in FIG. 1. The behavior is the same regardless of the polarity of the applied potential difference. In this way, row/column actuation that can control the reflective vs. non-reflective pixel states is analogous in many ways to that used in conventional LCD and other display technologies.

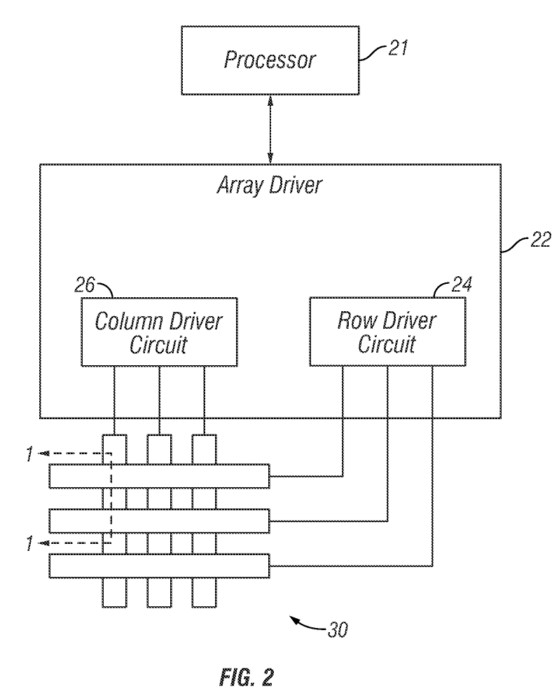

FIGS. 2 through 5 illustrate one exemplary process and system for using an array of interferometric modulators in a display application.

FIG. 2 is a system block diagram illustrating one embodiment of an electronic device that may incorporate aspects of the invention. In the exemplary embodiment, the electronic device includes a processor 21 which may be any general purpose single- or multi-chip microprocessor such as an ARM, Pentium®, Pentium II®, Pentium III®, Pentium IV®, Pentium® Pro, an 8051, a MIPS®, a Power PC®, an ALPHA®, or any special purpose microprocessor such as a digital signal processor, microcontroller, or a programmable gate array. As is conventional in the art, the processor 21 may be configured to execute one or more software modules. In addition to executing an operating system, the processor may be configured to execute one or more software applications, including a web browser, a telephone application, an email program, or any other software application.

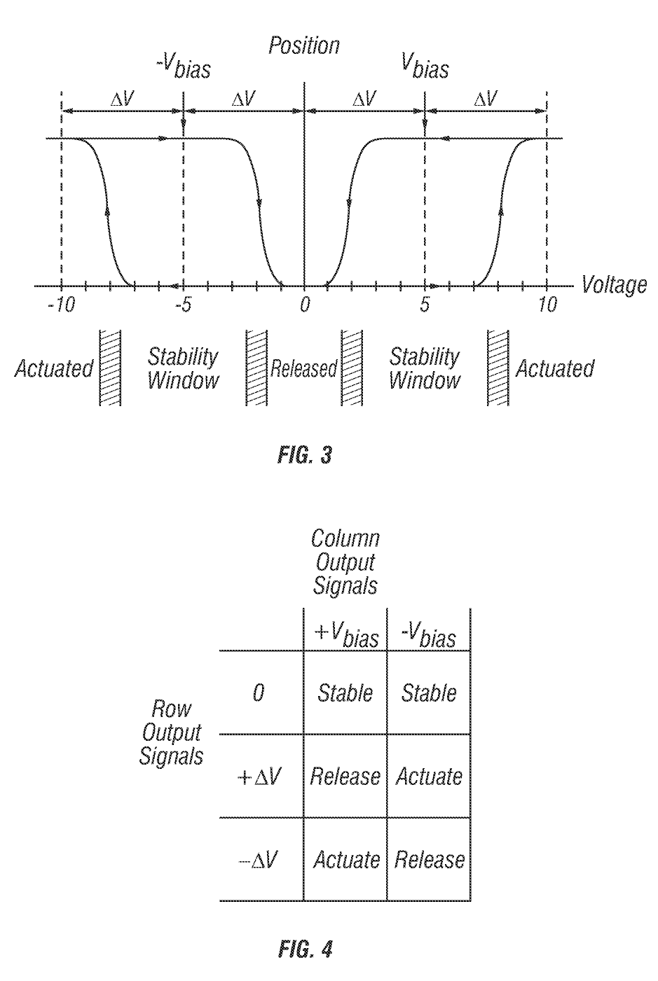

In one embodiment, the processor 21 is also configured to communicate with an array driver 22. In one embodiment, the array driver 22 includes a row driver circuit 24 and a column driver circuit 26 that provide signals to a panel or display array (display) 30. The cross section of the array illustrated in FIG. 1 is shown by the lines 1-1 in FIG. 2. For MEMS interferometric modulators, the row/column actuation protocol may take advantage of a hysteresis property of these devices illustrated in FIG. 3. It may require, for example, a 10 volt potential difference to cause a movable layer to deform from the relaxed state to the actuated state. However, when the voltage is reduced from that value, the movable layer maintains its state as the voltage drops back below 10 volts. In the exemplary embodiment of FIG. 3, the movable layer does not relax completely until the voltage drops below 2 volts. There is thus a range of voltage, about 3 to 7 V in the example illustrated in FIG. 3, where there exists a window of applied voltage within which the device is stable in either the relaxed or actuated state. This is referred to herein as the “hysteresis window” or “stability window.” For a display array having the hysteresis characteristics of FIG. 3, the row/column actuation protocol can be designed such that during row strobing, pixels in the strobed row that are to be actuated are exposed to a voltage difference of about 10 volts, and pixels that are to be relaxed are exposed to a voltage difference of close to zero volts. After the strobe, the pixels are exposed to a steady state voltage difference of about 5 volts such that they remain in whatever state the row strobe put them in. After being written, each pixel sees a potential difference within the “stability window” of 3-7 volts in this example. This feature makes the pixel design illustrated in FIG. 1 stable under the same applied voltage conditions in either an actuated or relaxed pre-existing state. Since each pixel of the interferometric modulator, whether in the actuated or relaxed state, is essentially a capacitor formed by the fixed and moving reflective layers, this stable state can be held at a voltage within the hysteresis window with almost no power dissipation. Essentially no current flows into the pixel if the applied potential is fixed.

In typical applications, a display frame may be created by asserting the set of column electrodes in accordance with the desired set of actuated pixels in the first row. A row pulse is then applied to the row 1 electrode, actuating the pixels corresponding to the asserted column lines. The asserted set of column electrodes is then changed to correspond to the desired set of actuated pixels in the second row. A pulse is then applied to the row 2 electrode, actuating the appropriate pixels in row 2 in accordance with the asserted column electrodes. The row 1 pixels are unaffected by the row 2 pulse, and remain in the state they were set to during the row 1 pulse. This may be repeated for the entire series of rows in a sequential fashion to produce the frame. Generally, the frames are refreshed and/or updated with new display data by continually repeating this process at some desired number of frames per second. A wide variety of protocols for driving row and column electrodes of pixel arrays to produce display frames are also well known and may be used in conjunction with the present invention.

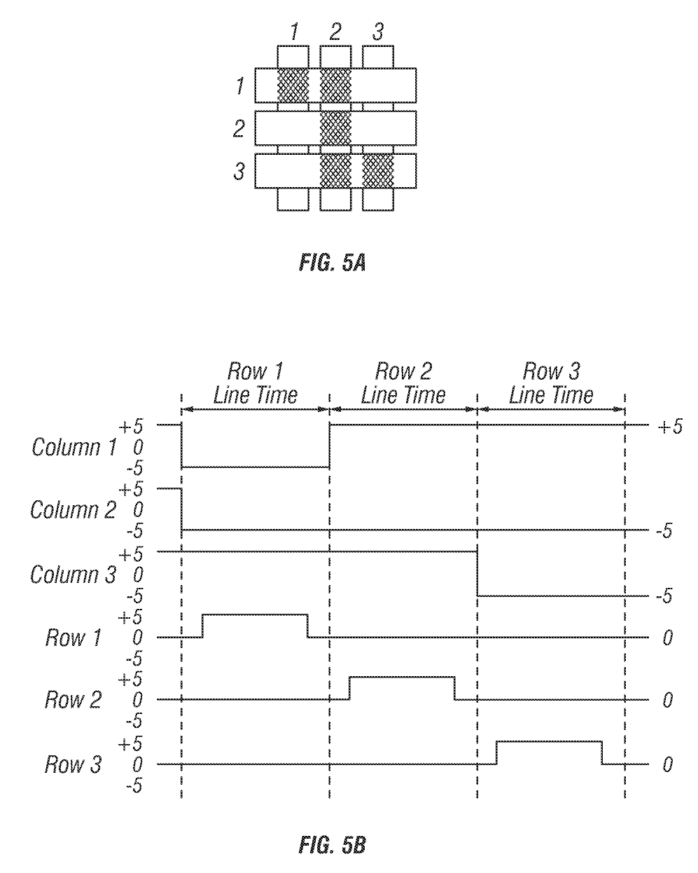

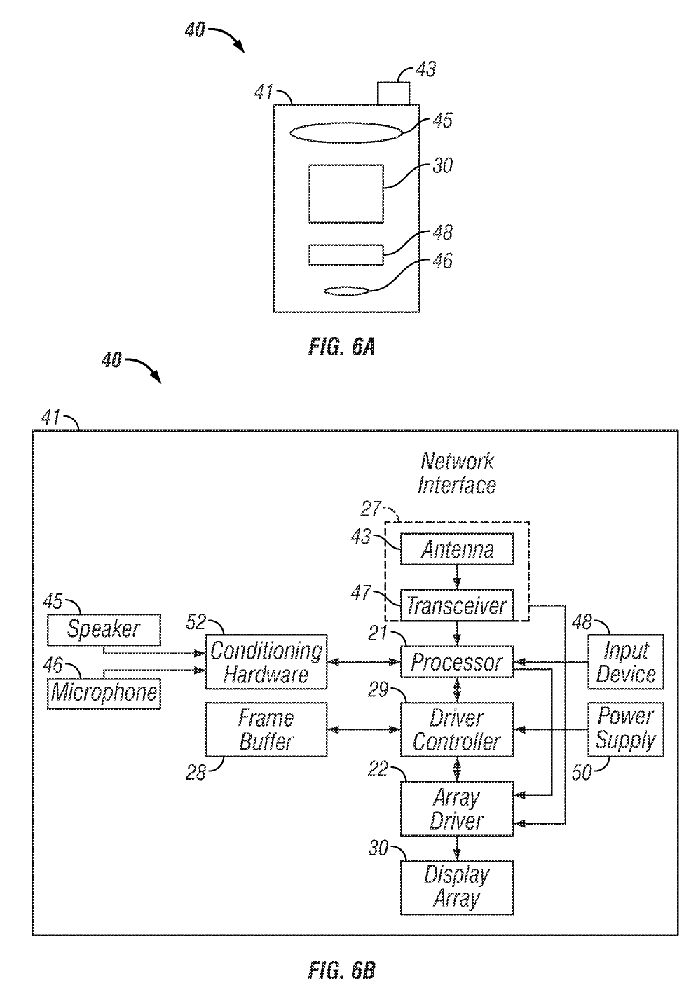

FIGS. 4 and 5 illustrate one possible actuation protocol for creating a display frame on the 312 array of FIG. 2. FIG. 4 illustrates a possible set of column and row voltage levels that may be used for pixels exhibiting the hysteresis curves of FIG. 3. In the FIG. 4 embodiment, actuating a pixel involves setting the appropriate column to −V_{bias}, and the appropriate row to +ΔV, which may correspond to −5 volts and +5 volts respectively. Relaxing the pixel is accomplished by setting the appropriate column to +V_{bias}, and the appropriate row to the same +ΔV, producing a zero volt potential difference across the pixel. In those rows where the row voltage is held at zero volts, the pixels are stable in whatever state they were originally in, regardless of whether the column is at +V_{bias}, or −V_{bias}. As is also illustrated in FIG. 4, it will be appreciated that voltages of opposite polarity than those described above can be used, e.g., actuating a pixel can involve setting the appropriate column to +V_{bias}, and the appropriate row to −ΔV. In this embodiment, releasing the pixel is accomplished by setting the appropriate column to −V_{bias}, and the appropriate row to the same −ΔV, producing a zero volt potential difference across the pixel.

FIG. 5B is a timing diagram showing a series of row and column signals applied to the 312 array of FIG. 2 which will result in the display arrangement illustrated in FIG. 5A, where actuated pixels are non-reflective. Prior to writing the frame illustrated in FIG. 5A, the pixels can be in any state, and in this example, all the rows are at 0 volts, and all the columns are at +5 volts. With these applied voltages, all pixels are stable in their existing actuated or relaxed states.

In the FIG. 5A frame, pixels (1,1), (1,2), (2,2), (3,2) and (3,3) are actuated. To accomplish this, during a “line time” for row 1, columns 1 and 2 are set to −5 volts, and column 3 is set to +5 volts. This does not change the state of any pixels, because all the pixels remain in the 3-7 volt stability window. Row 1 is then strobed with a pulse that goes from 0, up to 5 volts, and back to zero. This actuates the (1,1) and (1,2) pixels and relaxes the (1,3) pixel. No other pixels in the array are affected. To set row 2 as desired, column 2 is set to −5 volts, and columns 1 and 3 are set to +5 volts. The same strobe applied to row 2 will then actuate pixel (2,2) and relax pixels (2,1) and (2,3). Again, no other pixels of the array are affected. Row 3 is similarly set by setting columns 2 and 3 to −5 volts, and column 1 to +5 volts. The row 3 strobe sets the row 3 pixels as shown in FIG. 5A. After writing the frame, the row potentials are zero, and the column potentials can remain at either +5 or −5 volts, and the display is then stable in the arrangement of FIG. 5A. It will be appreciated that the same procedure can be employed for arrays of dozens or hundreds of rows and columns. It will also be appreciated that the timing, sequence, and levels of voltages used to perform row and column actuation can be varied widely within the general principles outlined above, and the above example is exemplary only, and any actuation voltage method can be used with the systems and methods described herein.

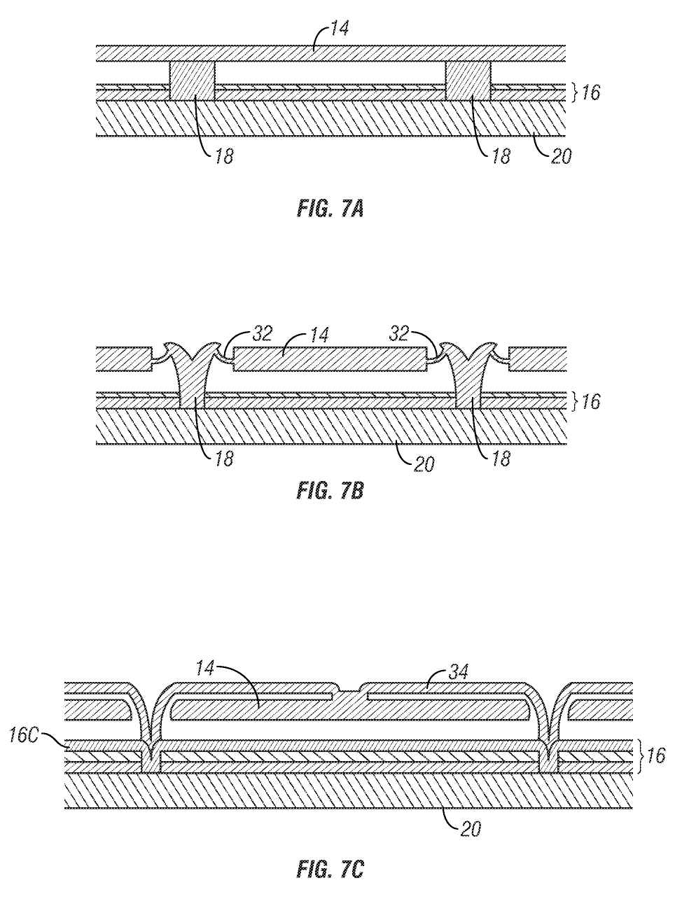

FIGS. 6A and 6B are system block diagrams illustrating an embodiment of a display device 40. The display device 40 can be, for example, a cellular or mobile telephone. However, the same components of display device 40 or slight variations thereof are also illustrative of various types of display devices such as televisions and portable media players.

The display device 40 includes a housing 41, a display 30, an antenna 43, a speaker 45, an input device 48, and a microphone 46. The housing 41 is generally formed from any of a variety of manufacturing processes as are well known to those of skill in the art, including injection molding, and vacuum forming. In addition, the housing 41 may be made from any of a variety of materials, including but not limited to plastic, metal, glass, rubber, and ceramic, or a combination thereof. In one embodiment the housing 41 includes removable portions (not shown) that may be interchanged with other removable portions of different color, or containing different logos, pictures, or symbols.

The display 30 of exemplary display device 40 may be any of a variety of displays, including a bi-stable display, as described herein. In other embodiments, the display 30 includes a flat-panel display, such as plasma, EL, OLED, STN LCD, or TFT LCD as described above, or a non-flat-panel display, such as a CRT or other tube device, as is well known to those of skill in the art. However, for purposes of describing the present embodiment, the display 30 includes an interferometric modulator display, as described herein.

The components of one embodiment of exemplary display device 40 are schematically illustrated in FIG. 6B. The illustrated exemplary display device 40 includes a housing 41 and can include additional components at least partially enclosed therein. For example, in one embodiment, the exemplary display device 40 includes a network interface 27 that includes an antenna 43 which is coupled to a transceiver 47. The transceiver 47 is connected to the processor 21, which is connected to conditioning hardware 52. The conditioning hardware 52 may be configured to condition a signal (e.g. filter a signal). The conditioning hardware 52 is connected to a speaker 45 and a microphone 46. The processor 21 is also connected to an input device 48 and a driver controller 29. The driver controller 29 is coupled to a frame buffer 28 and to the array driver 22, which in turn is coupled to a display array 30. A power supply 50 provides power to all components as required by the particular exemplary display device 40 design.

The network interface 27 includes the antenna 43 and the transceiver 47 so that the exemplary display device 40 can communicate with one or more devices over a network. In one embodiment the network interface 27 may also have some processing capabilities to relieve requirements of the processor 21. The antenna 43 is any antenna known to those of skill in the art for transmitting and receiving signals. In one embodiment, the antenna transmits and receives RF signals according to the IEEE 802.11 standard, including IEEE 802.11(a), (b), or (g). In another embodiment, the antenna transmits and receives RF signals according to the BLUETOOTH standard. In the case of a cellular telephone, the antenna is designed to receive CDMA, GSM, AMPS or other known signals that are used to communicate within a wireless cell phone network. The transceiver 47 pre-processes the signals received from the antenna 43 so that they may be received by and further manipulated by the processor 21. The transceiver 47 also processes signals received from the processor 21 so that they may be transmitted from the exemplary display device 40 via the antenna 43.

In an alternative embodiment, the transceiver 47 can be replaced by a receiver. In yet another alternative embodiment, network interface 27 can be replaced by an image source, which can store or generate image data to be sent to the processor 21. For example, the image source can be a digital video disc (DVD) or a hard-disc drive that contains image data, or a software module that generates image data.

Processor 21 generally controls the overall operation of the exemplary display device 40. The processor 21 receives data, such as compressed image data from the network interface 27 or an image source, and processes the data into raw image data or into a format that is readily processed into raw image data. The processor 21 then sends the processed data to the driver controller 29 or to frame buffer 28 for storage. Raw data typically refers to the information that identifies the image characteristics at each location within an image. For example, such image characteristics can include color, saturation, and gray-scale level.

In one embodiment, the processor 21 includes a microcontroller, CPU, or logic unit to control operation of the exemplary display device 40. Conditioning hardware 52 generally includes amplifiers and filters for transmitting signals to the speaker 45, and for receiving signals from the microphone 46. Conditioning hardware 52 may be discrete components within the exemplary display device 40, or may be incorporated within the processor 21 or other components.

The driver controller 29 takes the raw image data generated by the processor 21 either directly from the processor 21 or from the frame buffer 28 and reformats the raw image data appropriately for high speed transmission to the array driver 22. Specifically, the driver controller 29 reformats the raw image data into a data flow having a raster-like format, such that it has a time order suitable for scanning across the display array 30. Then the driver controller 29 sends the formatted information to the array driver 22. Although a driver controller 29, such as a LCD controller, is often associated with the system processor 21 as a stand-alone Integrated Circuit (IC), such controllers may be implemented in many ways. They may be embedded in the processor 21 as hardware, embedded in the processor 21 as software, or fully integrated in hardware with the array driver 22.

Typically, the array driver 22 receives the formatted information from the driver controller 29 and reformats the video data into a parallel set of waveforms that are applied many times per second to the hundreds and sometimes thousands of leads coming from the display's x-y matrix of pixels.

In one embodiment, the driver controller 29, array driver 22, and display array 30 are appropriate for any of the types of displays described herein. For example, in one embodiment, driver controller 29 is a conventional display controller or a bi-stable display controller (e.g., an interferometric modulator controller). In another embodiment, array driver 22 is a conventional driver or a bi-stable display driver (e.g., an interferometric modulator display). In one embodiment, a driver controller 29 is integrated with the array driver 22. Such an embodiment is common in highly integrated systems such as cellular phones, watches, and other small area displays. In yet another embodiment, display array 30 is a typical display array or a bi-stable display array (e.g., a display including an array of interferometric modulators).

The input device 48 allows a user to control the operation of the exemplary display device 40. In one embodiment, input device 48 includes a keypad, such as a QWERTY keyboard or a telephone keypad, a button, a switch, a touch-sensitive screen, a pressure- or heat-sensitive membrane. In one embodiment, the microphone 46 is an input device for the exemplary display device 40. When the microphone 46 is used to input data to the device, voice commands may be provided by a user for controlling operations of the exemplary display device 40.

Power supply 50 can include a variety of energy storage devices as are well known in the art. For example, in one embodiment, power supply 50 is a rechargeable battery, such as a nickel-cadmium battery or a lithium ion battery. In another embodiment, power supply 50 is a renewable energy source, a capacitor, or a solar cell, including a plastic solar cell, and solar-cell paint. In another embodiment, power supply 50 is configured to receive power from a wall outlet.

In some implementations control programmability resides, as described above, in a driver controller which can be located in several places in the electronic display system. In some cases control programmability resides in the array driver 22. Those of skill in the art will recognize that the above-described optimization may be implemented in any number of hardware and/or software components and in various configurations.

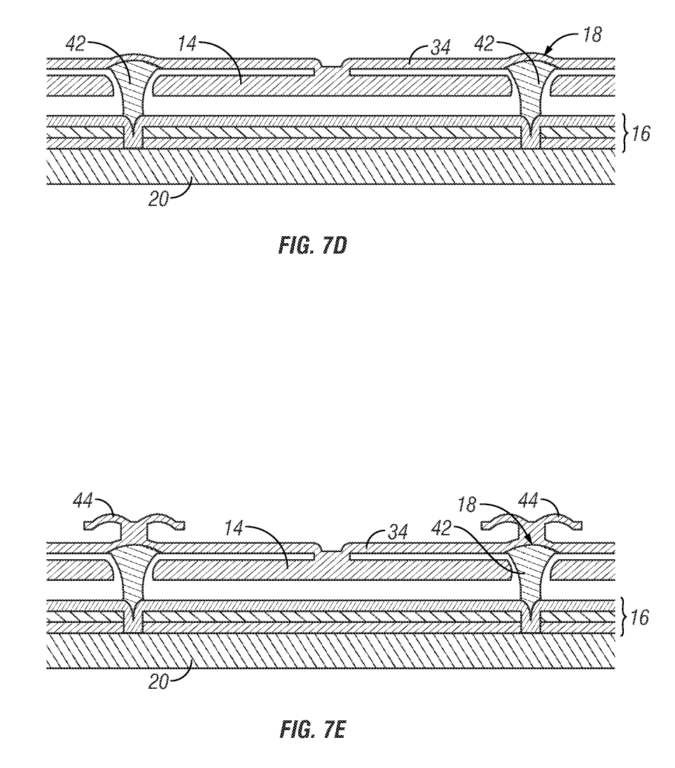

The details of the structure of interferometric modulators that operate in accordance with the principles set forth above may vary widely. For example, FIGS. 7A-7E illustrate five different embodiments of the movable reflective layer 14 and its supporting structures. FIG. 7A is a cross section of the embodiment of FIG. 1, where a strip of metal material 14 is deposited on orthogonally extending supports 18. In FIG. 7B, the moveable reflective layer 14 of each interferometric modulator is square or rectangular in shape and attached to supports at the corners only, on tethers 32. In FIG. 7C, the moveable reflective layer 14 is square or rectangular in shape and suspended from a deformable layer 34, which may comprise a flexible metal. The deformable layer 34 connects, directly or indirectly, to the substrate 20 around the perimeter of the deformable layer 34. These connections are herein referred to as support posts. The embodiment illustrated in FIG. 7D has support post plugs 42 upon which the deformable layer 34 rests. The movable reflective layer 14 remains suspended over the gap, as in FIGS. 7A-7C, but the deformable layer 34 does not form the support posts by filling holes between the deformable layer 34 and the optical stack 16. Rather, the support posts are formed of a planarization material, which is used to form support post plugs 42. The embodiment illustrated in FIG. 7E is based on the embodiment shown in FIG. 7D, but may also be adapted to work with any of the embodiments illustrated in FIGS. 7A-7C as well as additional embodiments not shown. In the embodiment shown in FIG. 7E, an extra layer of metal or other conductive material has been used to form a bus structure 44. This allows signal routing along the back of the interferometric modulators, eliminating a number of electrodes that may otherwise have had to be formed on the substrate 20.

In embodiments such as those shown in FIG. 7, the interferometric modulators function as direct-view devices, in which images are viewed from the front side of the transparent substrate 20, the side opposite to that upon which the modulator is arranged. In these embodiments, the reflective layer 14 optically shields the portions of the interferometric modulator on the side of the reflective layer opposite the substrate 20, including the deformable layer 34. This allows the shielded areas to be configured and operated upon without negatively affecting the image quality. For example, such shielding allows the bus structure 44 in FIG. 7E, which provides the ability to separate the optical properties of the modulator from the electromechanical properties of the modulator, such as addressing and the movements that result from that addressing. This separable modulator architecture allows the structural design and materials used for the electromechanical aspects and the optical aspects of the modulator to be selected and to function independently of each other. Moreover, the embodiments shown in FIGS. 7C-7E have additional benefits deriving from the decoupling of the optical properties of the reflective layer 14 from its mechanical properties, which are carried out by the deformable layer 34. This allows the structural design and materials used for the reflective layer 14 to be optimized with respect to the optical properties, and the structural design and materials used for the deformable layer 34 to be optimized with respect to desired mechanical properties.

An interferometric modulator is one type of a larger class of EMS devices referred to herein as capacitive EMS devices. Capacitive EMS devices also include capacitive EMS switches and cantilever beam devices. As mentioned above, electrostatic charging of a capacitive EMS device is strongly dependent on humidity. Aspects are described below which determine information regarding humidity based on the electrostatic charging of the EMS device. As noted above, where the term EMS is used, a MEMS device or a NEMS device is also contemplated. In one embodiment, the electrostatic charging is measured by determining an offset voltage shift.

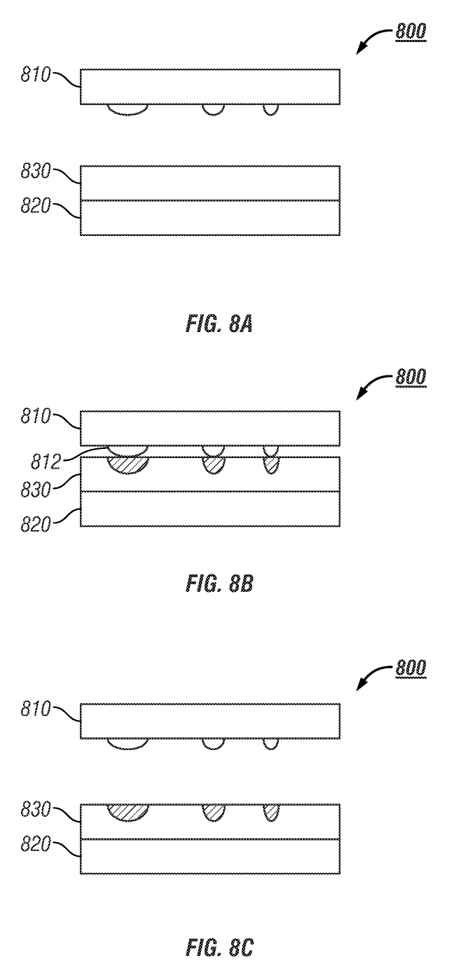

FIG. 8A is a diagram of an embodiment of a capacitive EMS device 800 in an unactuated state. The capacitive EMS device 800 of FIG. 8A comprises a first conductive layer 810 and a second conductive layer 820 spaced apart from the first layer 810. In between the first layer 810 and the second layer 820 is a dielectric 830. In one embodiment, the dielectric 830 comprises silicon dioxide. In the embodiment illustrated in FIG. 8A, the dielectric 830 is deposited onto the second layer 820. In other embodiments, the dielectric may be deposited onto the first layer 810 or separate from the layers.

As described above with respect to interferometric modulators and FIG. 3, when a voltage is applied between the first layer 810 and the second layer 820, the distance between the first layer 810 and the second layer 820 changes in response to the electrostatic attraction between the layers. If the magnitude of the voltage is sufficient, e.g., equal to or above an actuation threshold, the device actuates, and the first layer 810 (or at least a portion thereof) contacts the dielectric 830 as illustrated in FIG. 8B.

FIG. 8B is a diagram of an embodiment of a capacitive EMS device 800 in an actuated state. As shown in FIG. 8B, the lower surface of the first layer 810 may not be perfectly smooth, but rather may have one or more asperities 812 which contact the dielectric 830 when the device is actuated. These asperities 812 may be formed due to imperfections in the manufacturing process of the capacitive EMS device 800. Although asperities 812 are illustrated only for the first layer 810, the dielectric 830 may also have asperities due to imperfections in the manufacturing process.

Because a voltage is applied between the first layer 810 and the second layer 820 when the device 800 is actuated, charge may be deposited from the first layer 810 into the dielectric 830 at the contact points. The amount of charge deposited is affected by a number of different factors. When the voltage applied to the device 800 is greater, the amount of charge deposited is also greater. When the voltage applied to the device 800 is applied for a greater amount of time, the amount of charge deposited is also greater. When the humidity about the device 800 is greater, the amount of charge deposited is also greater.

As described above with respect to FIG. 3, when the applied voltage is removed or diminished below a release threshold, the device 810 releases and the first layer 810 moves away from the second layer 820 and the dielectric 830 as shown in FIG. 8C. Because the dielectric 830 is substantially insulting, the deposited charge remains at the location at which it is deposited. Thus, the dielectric 830 becomes electrostatically charged by actuation of the capacitive EMS device 800.

Charge within the dielectric 830 can shift the capacitance-voltage response of the capacitive EMS device 800. Solving the parallel plate capacitor model for the capacitive EMS device 800 with a sheet of charge, σₛₕₑₑₜ, within the dielectric 830, at a distance h from the second layer 820, results in an offset voltage of both the release (pull-out) and actuation (pull-in) threshold by an amount, V_{off}=h σₛₕₑₑₜ/(εᵣₑₗ εₒ), where εᵣₑₗ is the relative permittivity of the dielectric and εₒ is the permittivity of free space. For capacitive EMS devices the distance h can be approximated as equal to the dielectric thickness d_{ε}, because charge located near the dielectric surface has the greatest influence on offset voltage.

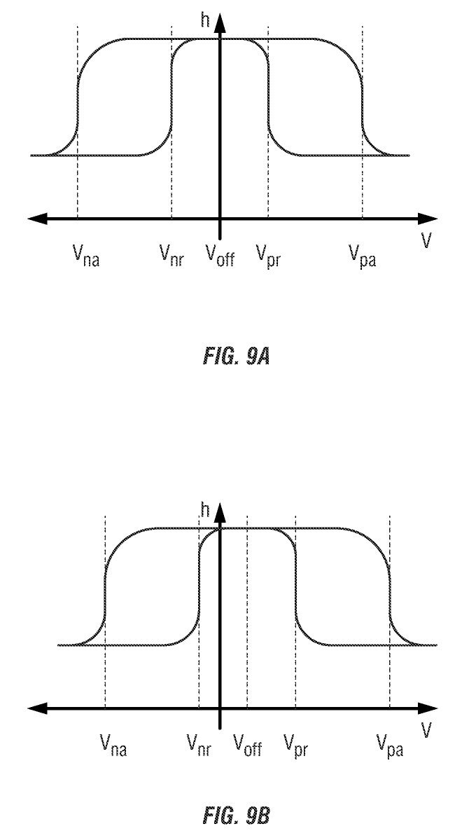

FIG. 9A is a diagram of the gap distance between a first layer of a capacitive EMS device and a second layer of the capacitive EMS device versus voltage applied between the two layers. As seen in FIG. 9A, the capacitive EMS device exhibits hysteresis as described above with respect to FIG. 3. When no voltage is applied between the first and second layers of a capacitive EMS device, the device is in a released (or unactuated) state. When the applied voltage is increased, the first layer moves towards the second layer and the gap distance decreases slightly. When the applied voltage is increased above a positive actuation potential (Vₚₐ), the device actuates and the gap distance is at a minimum. When the applied voltage is decreased below a positive release potential (Vₚᵣ), the device releases and the gap distance increases. As the applied voltage is further decreased the gap distances increases to a maximum and begins decreasing as the applied voltage is further decreased. When the applied voltage is decreased below a negative actuation potential (V.), the device actuates and the gap distance is again at a minimum. When the applied voltage increase above a negative release potential (Vₙᵣ), the device releases and the gap distance increases.

The voltage at which the gap distance is a maximum is referred to as the offset voltage (V_{off}). In the absence of electrostatic charge in a dielectric between the first and second layers, the offset voltage would theoretically be zero. However, this is usually not the case. Further, as described above, the electrostatic charge in the dielectric can be changed by actuation of the device, wherein the amount of the change is proportional to, among other things, the humidity.

FIG. 9B is a diagram of the gap distance versus voltage at a later time. The gap hysteresis curve and, therefore, the offset voltage are shifted as compared to the curve in FIG. 9A. This offset voltage shift can occur due to a change in the electrostatic charge in the dielectric. As mentioned above, the change in the electrostatic charge in the dielectric is dependent on, among other things, the humidity. Thus, by determining an offset voltage shift, information regarding humidity can also be determined.

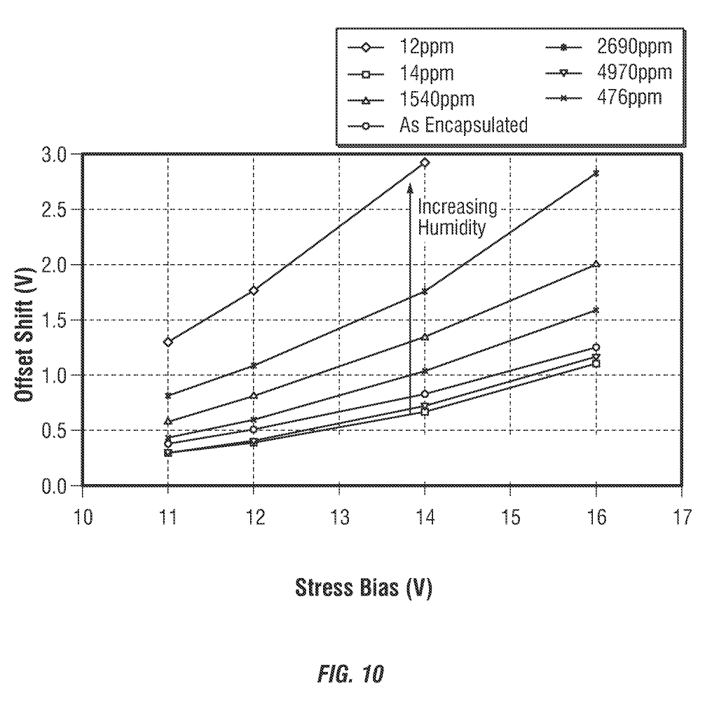

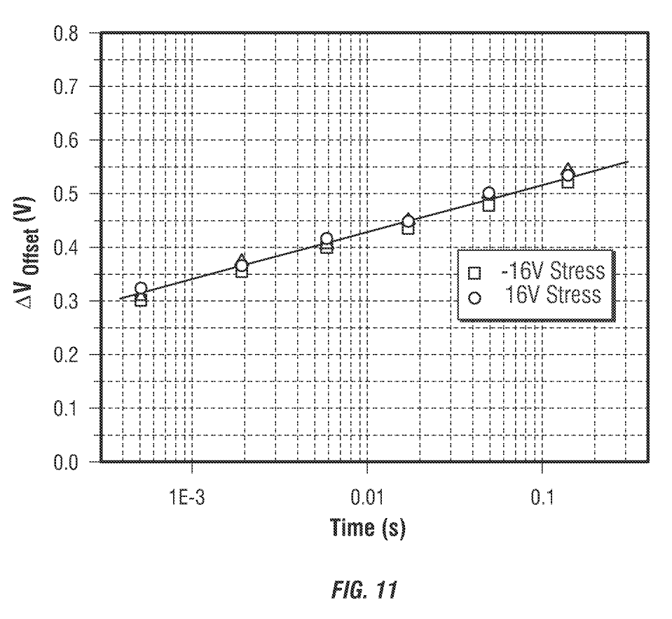

As mentioned above, the amount of charge deposited on a dielectric of a capacitive EMS device is affected by a number of different factors. Likewise, an offset voltage is dependent on a number of factors. When the voltage applied to the device is greater, the offset voltage shift is also greater. When the humidity about the device is greater the offset voltage shift is also greater. FIG. 10 is a plot of offset voltage shift versus applied voltage for different humidities. As can be seen in FIG. 10, the offset voltage shift is non-linearly dependent on the applied voltage. Rather, the dependence is superlinear. Further, as can be seen in FIG. 10, the offset voltage shift is also non-linearly dependent on the humidity. When the voltage applied to the device is applied for a greater time, the amount of charge deposited is also greater. FIG. 11 is a plot of offset voltage shift versus a stress time, e.g., the amount of time a voltage is applied. As can be seen in FIG. 11, the offset voltage shift is logarithmically dependent on the stress time. Mathematically, ΔV_{off}=Kₛ×log(tₛ), wherein ΔV_{off} is the offset voltage shift, tₛ is the stress time, and Kₛ is a proportionality constant which may depend on other variables, such as humidity and applied voltage.

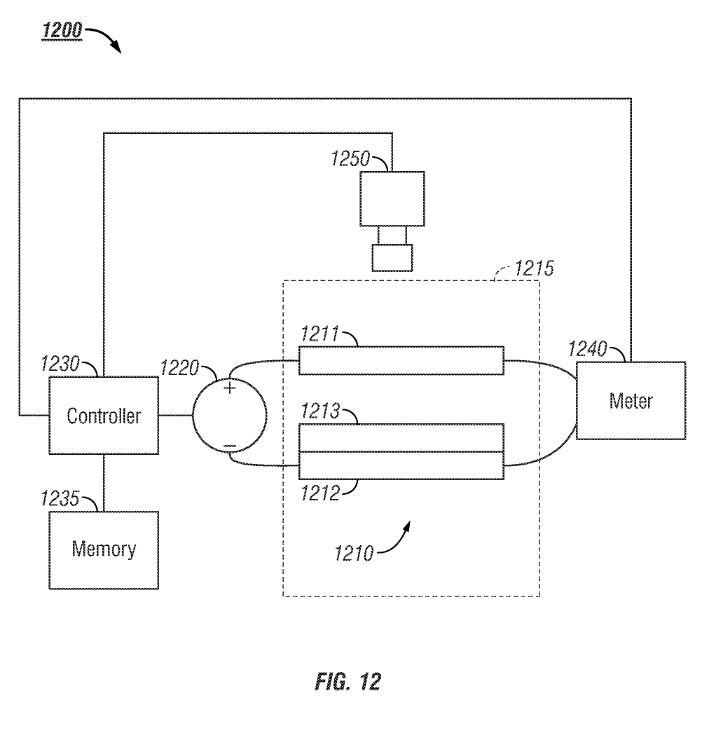

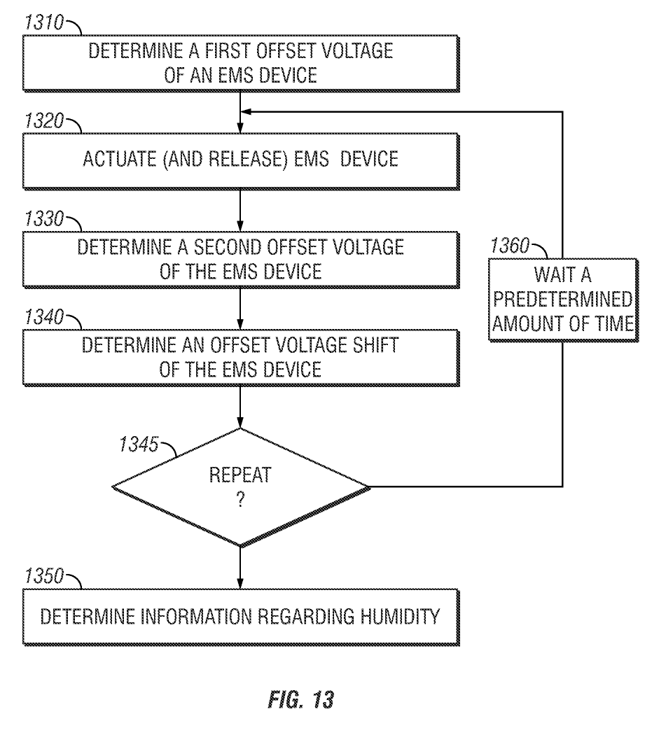

Knowledge of these relations allow for determination of information regarding humidity by determining an offset voltage shift. FIG. 12 is a functional block diagram of a system 1200 for determining information regarding humidity. The system 1200 includes a capacitive EMS device 1210 including a first layer 1211, a second layer 1212, and a dielectric 1213 between the two layers. The system 1200 also includes a voltage source 1220 configured to apply a voltage between the first layer 1211 and the second layer 1212 and a controller 1230 configured to control the voltage source 1220. In one embodiment, the controller 1230 is configured to control the voltage source 1220 to apply voltages, determine an offset voltage shift based on the applied voltages, and determine information regarding humidity based on the offset voltage shift. One method of performing these functions is described below with respect to FIG. 13.

The controller 1230 may be a general purpose processor, a digital signal processor (DSP), an application specific integrated circuit (ASIC), a field programmable gate array (FPGA) or other programmable logic device, discrete gate or transistor logic, discrete hardware components, or any suitable combination thereof designed to perform the functions described herein. The controller 1230 may also be implemented as a combination of computing devices, e.g., a combination of a DSP and a microprocessor, a plurality of microprocessors, one or more microprocessors in conjunction with a DSP core, or any other such configuration.

The controller 1230 may be coupled, via one or more buses, to read information from or write information to a memory 1235. The controller 1230 may additionally, or in the alternative, contain memory, such as processor registers. The memory 1235 may include processor cache, including a multi-level hierarchical cache in which different levels have different capacities and access speeds. The memory 1235 may also include random access memory (RAM), other volatile storage devices, or non-volatile storage devices.

In one embodiment, the memory 1235 stores processor-executable instructions for performing a method of determining information regarding humidity. In one embodiment, the memory 1235 stores one or more reference values. The reference values can include at least one of a reference humidity, a reference offset voltage shift, or a reference slope.

In one embodiment, the capacitive EMS device 1210 is within a sealed package 1215 and the system 1200 is configured to determine information regarding humidity within the package 1215. In another embodiment, the capacitive EMS device 1210 is not within a package 1215, but exposed to the environment, and the system 1200 is configured to determine information regarding humidity in the environment about the device 1210.

In one embodiment, the controller 1230 is operatively coupled to a meter 1240 configured to determine electrical parameters, such as capacitance, of the capacitive EMS device 1210. In one embodiment, the controller 1230 is operatively coupled to an optical system 1250 for determining mechanical parameters, such as gap distance, of the capacitive EMS device 1210. The meter 1240 can comprise a capacitance measuring circuit, a digital multimeter, or an LRC meter. The optical system 1250 can include a light source configured to illuminate the capacitive EMS device 1210 and a light detector configured to determine an intensity of light reflective from the capacitive EMS device 1210.

FIG. 13 is a flowchart illustrating a method 1300 of determining information regarding humidity. The method 1300 begins, in block 1310 with the determination of a first offset voltage of a device. The determining of the first offset voltage can be performed, for example, by the controller 1230 of FIG. 3. In one embodiment, the device is a capacitive EMS device having a first layer, a second layer, and a dielectric between the two layers.

Minimal charging occurs in a capacitive EMS device when the first layer is not in contact with the dielectric. There are a number of reasons that charging is minimal in the non-contacting state. Firstly, dielectric charging is dependent on electric field and only small electric fields can be applied without actuating the device. Secondly, in the non-contacting state, the ratio of the dielectric permittivity of air (approximately one) and the dielectric permittivity of the dielectric and the ratio of the dielectric thickness to the air gap result in small electric fields within the dielectric as compared to across the air gap. Thirdly, the air gap is a barrier for charge transport so any change in dielectric charging is generally due to a) injection from the second layer which is separated from the surface which contacts the first layer, or b) drifting along non-contacting regions of the device such as posts or rails (i.e., the structural materials separating the first layer from the dielectric) which is an inefficient process. However, as noted above, a capacitive MEMS devices can charge (resulting in offset voltage shifts) when the first layer is in contact with the dielectric. Therefore, in one embodiment, determining the first offset voltage in block 1310 does not involve contacting the first layer with the dielectric.

In one embodiment, a varying voltage waveform is applied to the device in a released state and the first offset voltage is determined based on measurements taken during application of the voltage waveform. The voltage waveform can be applied, for example, by the voltage source 1220 of FIG. 12. In one embodiment, the voltage waveform does not contain a voltage of sufficient magnitude to actuate the device. Rather, the gap distance varies about the offset voltage without actuating the device.

In one embodiment, the gap distance is determined by measuring the capacitance of the device as the voltage waveform is applied. The capacitance can be measured, for example, by the meter 1240 of FIG. 12. In a capacitive EMS device, the capacitance of the device is inversely related to the gap distance. Thus, by determining the voltage resulting in the minimum capacitance, the voltage at which gap distance is a maximum can also be determined. Thus, the offset voltage can be determined as the voltage resulting in the minimum capacitance. In one embodiment, the offset voltage is determined as the applied voltage at which the measured capacitance is minimized. In another embodiment, the measurements at a number of the applied voltages are used in a curve-fitting algorithm to determine the offset voltage.

In another embodiment, the gap distance is determined optically as the voltage waveform is applied. The gap distance can be determined, for example, by the optical system 1250 of FIG. 12. In an interferometric modulator, the reflectance of the device is influenced by gap distance as described above with respect to FIG. 3. Thus, by determining the voltage resulting in the maximum or minimum reflectance of the device, the voltage at which the gap distance is a maximum can also be determined. Thus, the offset voltage can be determined as the voltage resulting in the maximum or minimum reflectance. In one embodiment, the offset voltage is determined as the applied voltage at which the measured reflectance is maximized or minimized. In another embodiment, the measurements at a number of the applied voltages are used in a curve-fitting algorithm to determine the offset voltage. In another embodiment, laser Doppler vibrometry can be used to determine the gap distance.

Next, in block 1320, the device is actuated. In one embodiment, the device is actuated by applying a voltage above the positive actuation potential or below the negative actuation potential. The voltage can be applied, for example, by the voltage source 1220 of FIG. 12. In one embodiment, the device is actuated such that a first layer of the device contacts a dielectric of the device. In one embodiment, the device is actuated by applying a predetermined voltage for a predetermined amount of time. As described below, the predetermined voltage and predetermined amount of time can vary during different repetitions of the method 1300. Once the device is actuated, the device is released. In one embodiment, the device naturally releases once the applied voltage is removed.

Continuing, in block 1330, a second offset voltage is determined. The second offset voltage can be determined, for example, by the controller 1230 of FIG. 12. In one embodiment, the second offset voltage is determined in a similar manner as described above with respect to the first offset voltage in block 1310. In another embodiment, the second offset voltage is determined by determining the positive actuation potential and the negative actuation potential and defining the offset voltage as V_{off}=(Vₚₐ−Vₙₐ)/2. In another embodiment, the second offset voltage is determined by determining the positive release potential and the negative release potential and defining the offset voltage as V_{off}=(Vₚᵣ−Vₙᵣ)/2. In one embodiment, these potentials are determined by applying a voltage waveform having positive amplitudes sufficient to actuate the device and negative amplitudes sufficient to actuate the device. In one embodiment, the first offset voltage is similarly determined in block 1310.

As mentioned above with respect to block 1310, actuation of the device can result in charging of the dielectric and, therefore, reduce the accuracy of measuring the offset voltage. Thus, in order to improve the determination of the offset voltage shift measurement, in one embodiment, the amount of time that the device is actuated in determining the offset voltage shift is smaller than the amount of time that the device is actuated in block 1320, for example, an order of magnitude smaller. In another embodiment, in measuring the offset voltage shift, the device is equally positively actuated and negatively actuated.

Once the first and second offset voltages are determined, the method continues to block 1340 where an offset voltage shift is determined. The offset voltage shift can be determined, for example, by the controller 1230 of FIG. 12. In one embodiment, the offset voltage shift is determined as the difference between the first and second offset voltages. In one embodiment, the offset voltage shift is determined as proportional to the difference between the first and second offset voltages.

Next, in block 1345, it is determined whether to repeat the method 1300. The determination can be performed, for example, by the controller 1230 of FIG. 12. If it is determined to repeat the method 1300, the method 1300 continues to block 1320, optionally through block 1360 where the method 1300 waits a predetermined amount of time. The amount of time can vary depending on the repetition. If it is determined not to repeat the method 1300, the method 1300 continues to block 1350.

Finally, in block 1350, information regarding humidity is determined based on one or more of the determined offset voltage shifts. The determination of information regarding humidity can be determined, for example, by the controller 1230 of FIG. 12. The information regarding humidity can be stored in the memory 1235 of FIG. 12 or output via an output device, such as a printer or a display. Various forms of information regarding humidity which can be determined are described in detail below.

In one embodiment, the information regarding humidity includes a humidity value. In one embodiment, a look-up table is stored in the memory 1235 of FIG. 12. The look-up table stores a number of different offset voltage shifts with corresponding humidity values. In one embodiment, the controller 1230 determines the humidity value as that corresponding to the stored offset voltage shift closest to the determined offset voltage shift. In one embodiment, the look-up table is a multi-dimensional array in which a humidity value is associated with each combination of different offset voltage shifts, different applied voltages, and different stress times. Humidity values from about 1 to about 20,000 parts per million can be determined depending on device design and test parameters such as the applied voltage and the amount of time the voltage is applied.

In one embodiment, a function is stored in the memory 1235 of FIG. 12. The function is a coded representation of a mathematical equation relating the offset voltage shift to a humidity value. In one embodiment, the controller 1230 determines a humidity value as that resulting from applying the function to the determined offset voltage shift. In one embodiment, the mathematical equation relates the offset voltage shift, an applied voltage, and a stress time to a humidity value.

In one embodiment, the information regarding humidity includes a humidity change value. For example, if a first offset voltage shift is determined during a first repetition of the method 1300 and a second offset voltage shift is determined during a second repetition of the method 1300, the difference between these offset voltage shifts can be used to determine a humidity change value. In one embodiment, the humidity change value is determined by applying a stored function to the difference in the offset voltage shifts. In another embodiment, the difference in the offset voltage shifts can be determined using a determined offset voltage shift and a reference offset voltage shift. The reference offset voltage shift can be stored in the memory 1235 of FIG. 3. Humidity changes in the low parts per million can be measured, which for small volume packages can be converted to moisture changes of a few nanograms.

In one embodiment, the information regarding humidity includes determining that humidity has increased or decreased. For example, if a first offset voltage shift is determined during a first repetition of the method 1300 and a second offset voltage shift is determined during a second repetition of the method 1300, comparing these offset voltage shifts can indicate whether humidity is increasing or decreasing. For example, if the second offset voltage shift is greater than the first offset voltage shift, it can be determined that the humidity has increased. If the second offset voltage shift is less than the first offset voltage shift, it can be determined that the humidity has decreased.

As another example, the determined offset voltage shift can be compared to a reference offset voltage shift. The reference offset voltage shift can be stored in the memory 1235 of FIG. 12. In one embodiment, if the determined offset voltage shift is greater than the reference offset voltage shift, it is determined that the humidity has increased. If the determined offset voltage shift is less than the reference offset voltage shift, it is determined that the humidity has decreased.

In one embodiment, the information regarding humidity includes whether the humidity is acceptable or unacceptable. In one embodiment, if the offset voltage shift is greater than a reference offset voltage shift, it is determined that the humidity is unacceptable, whereas if the offset voltage shift is less than a reference offset voltage shift, it is determined that the humidity is acceptable.

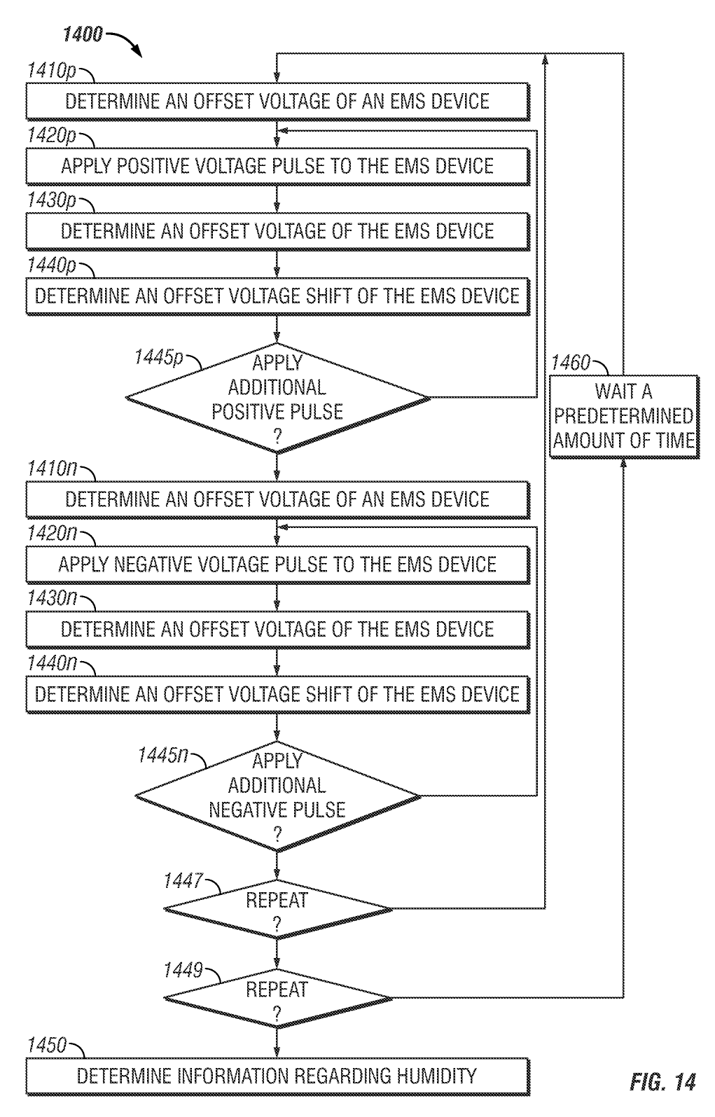

In one embodiment, described further with respect to FIG. 14, the information regarding humidity includes information of seal packaging quality.

FIG. 14 is a flowchart illustrating a method 1400 of determining information regarding humidity over time. The method 1400 begins in block 1410p with the determination of a first time-zero offset voltage of a capacitive EMS device. The determination can be performed as described above with respect to block 1310 of FIG. 13. The method 1400 continues to block 1420p with the application of a positive voltage pulse for an amount of time between a first and second layer of the capacitive EMS device. The application can be performed, for example, by the voltage source 1220 of FIG. 12. In one embodiment, the applied positive voltage pulse is applied for a greater amount of time in each iteration. In one embodiment, the applied positive voltage is applied for an amount of time which is logarithmically dependent on the iteration number.

The method 1400 continues to block 1430p with the determination of an offset voltage. The determination can be performed as described above with respect to block 1330 of FIG. 13. The method 1400 continues to block 1440p with the determination of an offset voltage shift. The determination can be performed, for example, by the controller 1230 of FIG. 12. In one embodiment, the offset voltage shift is determined as the difference between the offset voltage and the first time-zero offset voltage. Thus, at each iteration, the offset voltage shift is determined with respect to the first time-zero offset voltage rather than the latest offset voltage.

The method 1400 continues to block 1445p where it is determined whether to apply an additional positive voltage pulse. The determination can be performed, for example, by the controller 1230 of FIG. 12. If it is determined to apply an additional positive voltage pulse, the method 1400 returns to block 1420p. If it is determined not to apply an additional positive voltage pulse, the method 1400 continues to block 1410n. In one embodiment, the determination to apply an additional positive voltage pulse is based on the number of applied a positive voltage pulses such that a predetermined number of positive voltage pulses are applied. In another embodiment, the determination to apply an additional positive voltage pulse is based on whether the offset voltage shift has changed at least a threshold amount from a previous repetition.

Next, in block 1410n a second time-zero offset voltage is determined. In one embodiment, the determination is performed as described above with respect to block 1410p. In another embodiment, the determination is performed by selecting the latest offset voltage determined in block 1430p as the second time-zero offset voltage.

The method 1400 continues to block 1420n with the application of a negative voltage pulse of a negative voltage for an amount of time between a first and second layer of the capacitive EMS device. The application can be performed, for example, by the voltage source 1220 of FIG. 12. In one embodiment, the applied negative voltage pulse is applied for a greater amount of time in each iteration. In one embodiment, the applied negative voltage is applied for an amount of time which is logarithmically dependent on the iteration number.

The method 1400 continues to block 1430n with the determination of an offset voltage. The determination can be performed as described above with respect to block 1330 of FIG. 13. The method 1400 continues to block 1440n with the determination of an offset voltage shift. The determination can be performed, for example, by the controller 1230 of FIG. 12. In one embodiment, the offset voltage shift is determined as the difference between the offset voltage and the second time-zero offset voltage. Thus, at each iteration, the offset voltage shift is determined with respect to the second time-zero offset voltage rather than the latest offset voltage.

The method 1400 continues to block 1445n where it is determined whether to apply an additional negative voltage pulse. The determination can be performed, for example, by the controller 1230 of FIG. 12. If it is determined to apply an additional negative voltage pulse, the method 1400 returns to block 1420n. If it is determined not to apply an additional negative voltage pulse, the method 1400 continues to block 1447. In one embodiment, the determination to apply an additional negative voltage pulse is based on the number of applied a negative voltage pulses such that a predetermined number of negative voltage pulses are applied. In another embodiment, the determination to apply an additional negative voltage pulse is based on whether the offset voltage shift has changed at least a threshold amount from a previous repetition.

In block 1447, it is determined whether to repeat the positive-negative cycle, e.g., the actions performed in the blocks described above. The determination can be performed, for example, by the controller 1230 of FIG. 12. If it is determined to repeat the positive-negative cycle, the method returns to block 1410p. If it is determined not to repeat the positive-negative cycle, the method 1400 continues to block 1449. In one embodiment, the determination to repeat the positive-negative cycle is based on the number of positive-negative cycles performed such that a predetermined number of positive-negative cycles are performed. In another embodiment, the determination to repeat the positive-negative cycle is based on whether a steady-state is reached.

In block 1449, it is determined whether to perform another positive-negative measurement, e.g., actions performed in the blocks described above potentially including multiple positive-negative cycles. The determination can be performed, for example, by the controller 1230 of FIG. 12. If it is determined to perform another positive-negative measurement, the method returns to block 1410p through block 1460 where the method pauses for a predetermined amount of time. If it is determined not to repeat the positive-negative cycle, the method 1400 continues to block 1450.

In block 1460, the method 1400 paused for a predetermined amount of time. In one embodiment, a positive-negative cycle can be performed in a fraction of a second. Multiple positive-negative cycles can be performed in less than a second. This is advantageous because device reliability issues such as stiction or contact creep are less likely to effect the measurements. In contrast, the predetermined amount of time of block 1460 can be a few hours, a day, or multiple days. Thus, the predetermined amount of time that the method 1400 pauses can be 3, 4, 5, 6, or 7 orders of magnitude greater than the amount of time taken to perform a positive-negative cycle or 3, 4, 5, 6, or 7 orders of magnitude greater than the amount of time taken to perform a positive-negative measurement.

Finally, in block 1450 information regarding humidity is determined based on the determined offset voltage shift. The determination can be performed, for example, by the controller 1230 of FIG. 12. Various types of information regarding humidity can be determined as described above with respect to block 1350 of FIG. 13. A particular type of information regarding humidity is described below.

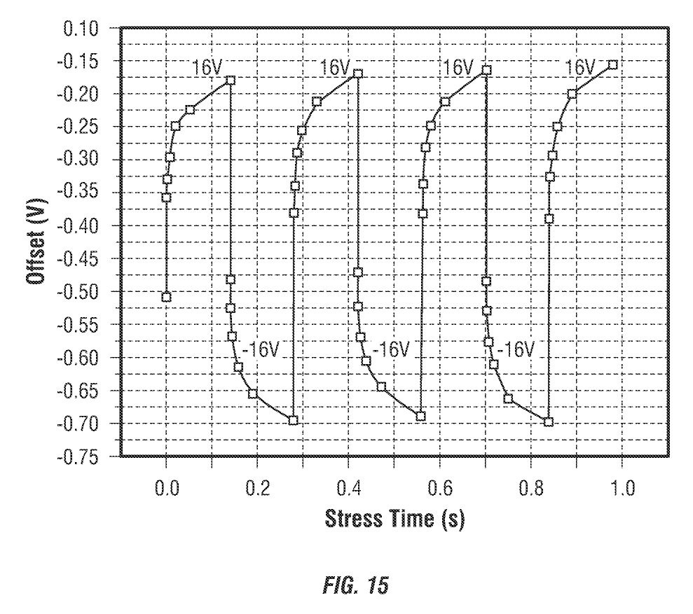

The determined offset voltages for one exemplary positive-negative measurement are plotted in FIG. 15. FIG. 15 is a plot of offset voltage versus cumulative stress time. As described above, in one embodiment, multiple positive voltage pulses are applied for different increasing stress times and multiple negative voltage pulses are applied for different increasing stress times. From these offset voltages, the offset voltage shift for various stress times can be determined as shown in FIG. 11. As described above with respect to FIG. 11, the offset voltage shift is logarithmically dependent on the stress time. Mathematically, ΔV_{off}=Kₛ×log(tₛ), wherein ΔV_{off} is the offset voltage shift, tₛ is the stress time, and Kₛ is a proportionality constant which may depend on other variables, such as humidity and applied voltage. Thus, the determined offset voltage shifts can be used to determine Kₛ, which is independent of stress time for a particular positive-negative measurement.

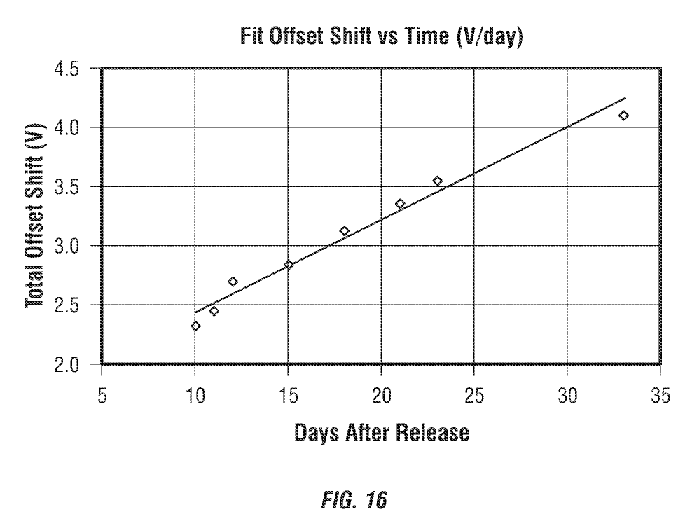

The determined Kₛ can be used to determine an adjusted offset voltage shift which is independent of stress time. The adjusted offset voltage shift can be determined for a number of positive-negative measurements performed at different times. FIG. 16 is a plot of adjusted offset voltage shift over time. Each adjusted offset voltage shift can be used to determine a humidity value as described above.

In one embodiment, a look-up table is stored in the memory 1235 of FIG. 12. The look-up table stores a number of different adjusted offset voltage shifts with corresponding humidity values. In one embodiment, the controller 1230 determines the humidity value as that corresponding to the stored adjusted offset voltage shift closest to the determined adjusted offset voltage shift. In one embodiment, the humidity value is determined by interpolating between two or more stored humidity values. In one embodiment, a function is stored in the memory 1235 of FIG. 12. The function is a coded representation of a mathematical equation relating the adjusted offset voltage shift to a humidity value. In one embodiment, the controller 1230 determines a humidity value as that resulting from applying the function to the determined offset voltage shift.

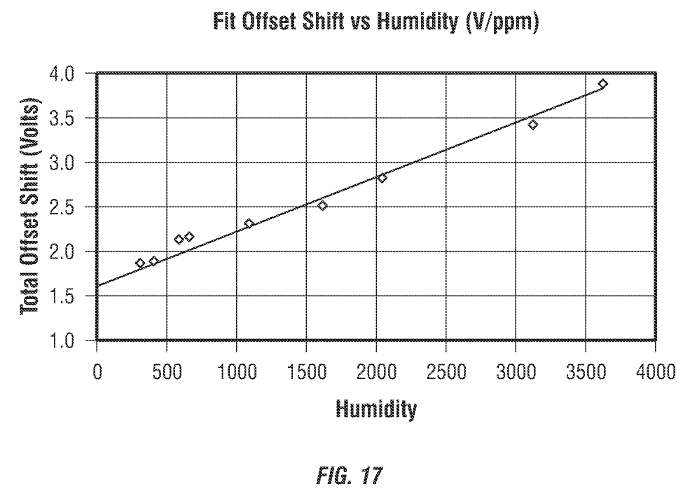

FIG. 17 is a plot of adjusted offset voltage shift versus humidity value for an exemplary embodiment. In the illustrated case, the humidity value can be approximated by a linear function over the illustrated range.

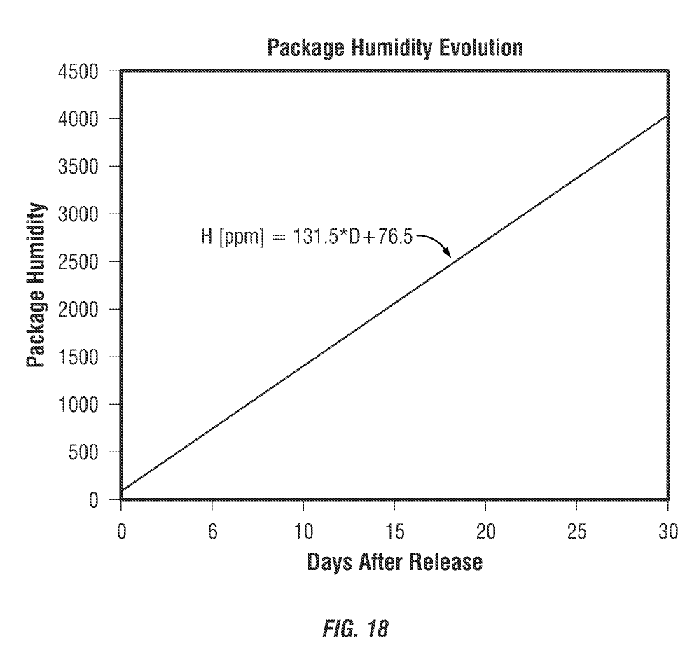

Because each adjusted offset voltage shift can be used to determine a humidity value, a humidity value can be determined for each positive-negative measurement and each time at which a positive-negative measurement was taken. Information regarding humidity can be determined from this data. FIG. 18 is a plot of humidity versus time for an exemplary embodiment. In FIG. 18, the humidity increases linearly over time, resulting in information regarding the humidity at time zero and a rate of humidity change. Accordingly, the information regarding humidity can include a humidity value of an earlier time or a rate of humidity change. If the capacitive EMS device under test is within a package, this information can be used to determine the initial humidity within the package or a metric of the seal packaging quality. Accordingly, the information regarding humidity can include an initial humidity within a package or a metric of the seal packaging quality. For example, in FIG. 18, the seal packaging quality can be described as about 132 parts per million per day.

Using the method 1400 described above with respect to FIG. 14, various packaging structure or methods can be tested for efficacy. The quality of a package, such as the package environment or the seal quality can be determined. Similarly, the effectiveness of various desiccants can be determined.

It is also to be recognized that, depending on the embodiment, the acts or events of any methods described herein can be performed in other sequences, may be added, merged, or left out altogether (e.g., not all acts or events are necessary for the practice of the methods), unless the text specifically and clearly states otherwise.

While the above description points out certain novel features of the invention as applied to various embodiments, the skilled person will understand that various omissions, substitutions, and changes in the form and details of the device or process illustrated may be made without departing from the scope of the invention. Therefore, the scope of the invention is defined by the appended claims rather than by the foregoing description. All variations coming within the meaning and range of equivalency of the claims are embraced within their scope.

What is claimed is:

1. A method of determining information regarding humidity, the method comprising:
determining an offset voltage shift of an electromechanical device; and
determining information regarding humidity about the device based on the offset voltage shift.

2. The method of claim 1, wherein the electromechanical device is within a sealed package and wherein the information regarding humidity comprises information regarding humidity within the package.

3. The method of claim 1, wherein determining an offset voltage shift comprises:
determining a first offset voltage;
determining a second offset voltage; and
determining the offset voltage shift as the difference between the first offset voltage and the second offset voltage.

4. The method of claim 3, further comprising actuating the electromechanical device after determining the first offset voltage and before determining the second offset voltage.

5. The method of claim 4, wherein the electromechanical device comprises a first layer, a second layer, and a dielectric between the layers, wherein the dielectric is spaced apart from at least one of the first and second layers in an unactuated state of the electromechanical device, and wherein the dielectric contacts both the first and second layers in an actuated state of the electromechanical device.

6. The method of claim 5, wherein actuating the electromechanical device comprises applying, between the first and second layers, a voltage sufficient to actuate the device.

7. The method of claim 6, further comprising, after determining the second offset voltage, repeatedly actuating the electromechanical device and determining additional offset voltages, wherein repeatedly actuating the electromechanical device comprises applying, between the first and second layers, actuation voltages of different amplitudes, including both positive and negative amplitudes.

8. The method of claim 7, wherein repeatedly actuating the electromechanical device comprises applying, between the first and second layers, an actuation voltage for different actuation times.

9. The method of claim 5, wherein determining at least one of the first or second offset voltage comprises:
applying, between the first and second layers, a plurality of different voltages insufficient to actuate the device; and
estimating a voltage resulting in a minimum gap distance.

10. The method of claim 9, wherein estimating a voltage resulting in a minimum gap distance comprises electrically measuring a capacitance at the plurality of different voltages.

11. The method of claim 9, wherein estimating a voltage resulting in a minimum gap distance comprises optically measuring a gap distance at the plurality of different voltages.

12. The method of claim 1, wherein determining information regarding humidity comprises determining information regarding humidity based on the offset voltage shift, an actuation voltage, and an actuation time.

13. The method of claim 1, wherein determining information regarding humidity comprises determining a value indicative of the humidity.

14. The method of claim 1, wherein determining information regarding humidity comprises determining a value indicative of a change in humidity.

15. The method of claim 1, wherein determining information regarding humidity comprises determining that the humidity has increased or decreased.

16. The method of claim 1, wherein determining information regarding humidity comprises determining information regarding humidity based on the offset voltage shift, a reference humidity, and a reference offset voltage shift.

17. The method of claim 1, wherein determining information regarding humidity comprises determining information regarding humidity based on the offset voltage shift, a reference humidity, and a reference slope.

18. A system for determining humidity, the system comprising:
an electromechanical device comprising a first layer, a second layer, and a dielectric between the two layers wherein the dielectric is spaced apart from at least one of the first and second layers in an unactuated state of the electromechanical device, and wherein the dielectric contacts both the first and second layers in an actuated state of the electromechanical device;
a voltage source configured to apply, between the first and second layers, one or more voltages; and
a processor configured to control the voltage source, to determine an offset voltage shift based on the applied voltages, and to determine information regarding humidity about the device based on the offset voltage shift.

19. The system of claim 17, further comprising a sealed package, wherein the electromechanical device is within the package and wherein the information regarding humidity comprises information regarding humidity within the package.

20. The system of claim 17, wherein the processor is configured to:
determine a first offset voltage;
control the voltage source to apply a voltage sufficient to actuate the electromechanical device;
determine a second offset voltage; and
determine the offset voltage shift as the different between the first offset voltage and the second offset voltage.

21. The system of claim 19, wherein the processor is configured to determine at least one of the first or second offset voltages by controlling the voltage source to apply a plurality of different voltages insufficient to actuate the device and estimating a voltage resulting in a minimum gap distance.

22. The system of claim 20, further comprising a meter configured to measure a capacitance between the first and second layer, wherein the processor is configured to determine the voltage resulting in a minimum gap distance based on one or more measured capacitances.

23. The system of claim 20, further comprising a light detector configured to measure a gap distance between the first and second layer, wherein the processor is configured to determine the voltage resulting in a minimum gap distance based on one or more measured gap distances.

24. The system of claim 17, wherein the processor is configured to determine a value indicative of humidity, determine a value indicative of a change in humidity, or determine that humidity has increased or decreased.

25. The system of claim 23, further comprising a memory storing at least one of a reference humidity or a reference offset voltage shift, wherein the processor is configured to determine information regarding humidity based on at least one reference value stored in the memory.

26. The system of claim 17, wherein the processor is configured to control the voltage source so as to repeatedly actuating the electromechanical device and to determine additional offset voltages, wherein the voltage source applies actuation voltages of different amplitudes, including both positive and negative amplitudes.

27. The system of claim 25, wherein the voltage source applies an actuation voltage for different actuation times.

28. A system for determining information regarding humidity, the system comprising:
means for determining an offset voltage shift of an electromechanical device; and
means for determining information regarding humidity about the device based on the offset voltage shift.

29. A computer-readable storage medium having computer-executable instructions encoded thereon for performing a method of determining information regarding humidity, the method comprising:
determining an offset voltage shift of an electromechanical device; and
determining information regarding humidity about the device based on the offset voltage shift.
